(19) United States
(12) Patent Application Publication
(10) Pub. No.: US 2017/0236913 A1
(43) Pub. Date: Aug. 17, 2017

(54) Method of Processing a Semiconductor Device

(71) Applicant: Infineon Technologies Austria AG, Villach (AT)

(72) Inventors: Heimo Hofer, Bodensdorf (AT); Martin Poelzl, Ossiach (AT); Britta Wutte, Feistritz (AT)

(21) Appl. No.: 15/427,099

(22) Filed: Feb. 8, 2017

(30) Foreign Application Priority Data
Feb. 11, 2016 (DE) 102016102422.8

(51) Int. Cl. H01L 29/423; H01L 21/768; H01L 21/3213; H01L 21/02; H01L 29/66; H01L 21/3205; H01L 21/3105; H01L 29/40; H01L 29/417; H01L 21/306; H01L 21/311

(52) U.S. Cl. CPC H01L 29/4236; H01L 21/30604; H01L 21/76831; H01L 21/76877; H01L 21/32139; H01L 21/02274; H01L 21/31116; H01L 21/32055; H01L 21/31055; H01L 29/407; H01L 29/41766; H01L 29/66666; H01L 29/6634; H01L 29/66356

(57) ABSTRACT

A method of processing a semiconductor device includes: creating first and second recesses in a surface of a semiconductor body; creating an insulation layer that forms first and second wells each having a common lateral extension range with the portion of the insulation layer located between the recesses; filling the wells with a plug material having the respective common lateral extension range with the insulation layer; removing a middle portion of the insulation layer located between the recesses; filling, with a filling material, a third recess created in a region where the middle portion has been removed and at least a portion of the space located between the wells; creating a first common surface of the insulation layer, the plug material, and the filling material; removing the plug material from the second well; and creating a second insulation layer that covers a side wall of the second recess.

### TECHNICAL FIELD

This specification refers to embodiments of a method of processing a semiconductor device. In particular, this specification refers to embodiments of a method of processing a semiconductor device including a MOS gated diode (MGD).

### BACKGROUND

Many functions of modern devices in automotive, consumer and industrial applications, such as converting electrical energy and driving an electric motor or an electric machine, rely on semiconductor devices. For example, insulated gate bipolar transistors (IGBTs), metal oxide semiconductor field effect transistors (MOSFETs) and diodes, to name a few, have been used for various applications including, but not limited to switching in power supplies and power converters.

A semiconductor device is usually configured to conduct a load current along a load current path between two load terminals of the device. The load current path may be controlled by means of a first control electrode, sometimes referred to as gate electrode. For example, upon receiving a corresponding control signal from, e.g., a driver unit, the gate electrode may set the semiconductor device in one of a conducting state and a blocking state. The gate electrode may be arranged within a first recess, such as a trench, extending into a semiconductor body of the semiconductor device.

For example, the semiconductor device may be configured to form a depletion region (sometimes also referred to as “space charge region”) at a pn-junction formed at the transition between a body region having dopants of the first conductivity type and a drift region having dopants of a second conductivity type complementary to the first conductivity type.

Occasionally, a second control electrode is provided for controlling a reverse current path through the semiconductor device in an operating state wherein a voltage is applied between the load terminals such that the pn-junction is forward biased. Such a configuration is sometimes referred to as a MOS gate diode (MGD). The second control electrode (in the following also referred to as “MGD gate electrode”) may be arranged in a second recess, such as a trench, extending into the semiconductor body.

To this end, a first control electrode and a second control electrode may need to be created within a respective recess extending into the semiconductor body, wherein each control electrode is insulated from the semiconductor body by a first and second insulation layer, respectively. Further, it may be required to provide a thickness of the fist insulation layer that is different from a thickness of the second insulation layer.

### SUMMARY

According to an embodiment, a method of processing a semiconductor device is presented. The method comprises providing a semiconductor body having a surface; creating a first recess and a second recess, each recess extending into the semiconductor body from the surface along a vertical direction, wherein each recess has a recess bottom and is laterally confined by at least one recess sidewall; creating the first insulation layer that covers the recess bottom of each recess, the at least one recess side wall of each recess, and at least a portion of the surface located between the first recess and the second recess, such that the first insulation layer forms a first well at the first recess and a second well at the second recess, wherein the first well and the second well each have a respective common lateral extension range with the portion of the first insulation layer located between the first recess and the second recess; filling the first well and the second well at least partially with a plug material, such that the plug material has said respective common lateral extension range with the portion of the first insulation layer located between the first recess and the second recess; removing a middle portion of the first insulation layer located between the first recess and the second recess from the surface, wherein the middle portion does not have a common lateral extension range with the plug material; creating, in a region where the middle portion of the first insulation layer has been removed, a third recess that extends into the semiconductor body from the surface along the vertical direction; filling the third recess and at least a portion of the space located between the first well and the second well with the filling material; creating a first common surface of the first insulation layer, the plug material, and the filling material, wherein the first common surface is essentially planar and parallel to the surface; creating on the common surface a mask that completely covers the plug material in the first well and that does not completely cover the plug material in the second well; removing the plug material from the second well; and creating a second insulation layer that covers the at least one recess side wall of the second recess.

Those skilled in the art will recognize additional features and advantages upon reading the following detailed description, and upon viewing the accompanying drawings.

### BRIEF DESCRIPTION OF THE DRAWINGS

The parts in the figures are not necessarily to scale, instead emphasis being placed upon illustrating principles of the invention. Moreover, in the figures, like reference numerals designate corresponding parts. In the drawings:

FIGS. 1A-1K schematically illustrate different stages of a semiconductor device processing method by means of a respective schematic illustration of a section of a vertical cross-section of a semiconductor device in accordance with one or more embodiments;

FIGS. 2A-2E schematically illustrate further stages of a semiconductor device processing method by means of a schematic illustration of a section of the vertical cross-section of a semiconductor device in accordance with one or more embodiments;

FIG. 3 schematically illustrates a further stage of the semiconductor device processing method by means of a schematic illustration of a section of a vertical cross-section of a semiconductor device in accordance with one or more embodiments;

FIG. 4 schematically illustrates a section of a vertical cross-section of a semiconductor device produced using a semiconductor device processing method in accordance with one or more embodiments;

FIGS. 5A-5C schematically illustrate further stages of a semiconductor device processing method by means of a schematic illustration of a section of the vertical cross-section of a semiconductor device in accordance with one or more embodiments; and

FIGS. 6A-6B schematically illustrates further stages of a semiconductor device processing method by means of a schematic illustration of a section of the vertical cross-section of a semiconductor device in accordance with one or more embodiments.

### DETAILED DESCRIPTION

In the following detailed description, reference is made to the accompanying drawings which form a part hereof and in which are shown by way of illustration specific embodiments in which the invention may be practiced.

In this regard, directional terminology, such as “top”, “bottom”, “below”, “front”, “behind”, “back”, “leading”, “trailing”, “below”, “above” etc., may be used with reference to the orientation of the Figs. being described. Because parts of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

Reference will now be made in detail to various embodiments, one or more examples of which are illustrated in the figures. Each example is provided by way of explanation, and is not meant as a limitation of the invention. For example, features illustrated or described as part of one embodiment can be used on or in conjunction with other embodiments to yield yet a further embodiment. It is intended that the present invention includes such modifications and variations. The examples are described using specific language which should not be construed as limiting the scope of the appended claims. The drawings are not scaled and are for illustrative purposes only. For clarity, the same elements or manufacturing steps have been designated by the same references in the different drawings if not stated otherwise.

The term “horizontal” as used in this specification intends to describe an orientation substantially parallel to a horizontal surface of a semiconductor substrate or of a semiconductor body. This can be for instance the surface of a semiconductor wafer or a die. For example, both the first lateral direction X and the second lateral direction Y mentioned below can be horizontal directions, wherein the first lateral direction X and the second lateral direction Y may be perpendicular to each other.

The term “vertical” as used in this specification intends to describe an orientation which is substantially arranged perpendicular to the horizontal surface, i.e., parallel to the normal direction of the surface of the semiconductor wafer. For example, the extension direction Z mentioned below may be a vertical direction Z is perpendicular to both the first lateral direction X and the second lateral direction Y.

In this specification, n-doped is referred to as “first conductivity type” while p-doped is referred to as “second conductivity type”. Alternatively, opposite doping relations can be employed so that the first conductivity type can be p-doped and the second conductivity type can be n-doped.

Further, within this specification, the term “dopant concentration” may refer to an average dopant concentration or, respectively, to a mean dopant concentration or to a sheet charge carrier concentration of a specific semiconductor region or semiconductor zone, such as a semiconductor region within a trench. Thus, e.g., a statement saying that a specific semiconductor region exhibits a certain dopant concentration that is higher or lower as compared to a dopant concentration of another semiconductor region may indicate that the respective mean dopant concentrations of the semiconductor regions differ from each other.

In the context of the present specification, the terms “in ohmic contact”, “in electric contact”, “in ohmic connection”, and “electrically connected” intend to describe that there is a low ohmic electric connection or low ohmic current path between two regions, sections, zones, portions or parts of a semiconductor device or between different terminals of one or more devices or between a terminal or a metallization or an electrode and a portion or part of a semiconductor device. Further, in the context of the present specification, the term “in contact” intends to describe that there is a direct physical connection between two elements of the respective semiconductor device; e.g., a transition between two elements being in contact with each other may not include a further intermediate element or the like.

In addition, in the context of the present specification, the term “electric insulation” is used, if not stated otherwise, in the context of its general valid understanding and thus intends to describe that two or more components are positioned separately from each other and that there is no ohmic connection connecting those components. However, components being electrically insulated from each other may nevertheless be coupled to each other, for example mechanically coupled and/or capacitively coupled and/or inductively coupled. To give an example, two electrodes of a capacitor may be electrically insulated from each other and, at the same time, mechanically and capacitively coupled to each other, e.g., by means of an insulation, e.g., a dielectric.

Specific embodiments described in this specification pertain to, without being limited thereto, a power semiconductor device, such as a power semiconductor transistor, that may be used within a power converter or a power supply. Thus, in an embodiment, the semiconductor device is configured for carrying a load current that is to be fed to a load and/or, respectively, that is provided by a power source. For example, the semiconductor device may comprise one or more active power semiconductor cells, such as a monolithically integrated diode cell, and/or a monolithically integrated transistor cell, and/or a monolithically integrated IGBT cell, and/or a monolithically integrated RC-IGBT cell, and/or a monolithically integrated MOS Gated Diode (MGD) cell, and/or a monolithically integrated MOSFET cell and/or derivatives thereof. Such diode cell and/or such transistor cells may be integrated in a power semiconductor module.

The term “power semiconductor device” as used in this specification intends to describe a semiconductor device on a single chip with high voltage blocking and/or high current-carrying capabilities. In other words, such power semiconductor device is intended for high current, typically in the Ampere range, e.g., up to several ten or hundred Ampere, and/or high voltages, typically above 15 V, more typically 100 V and above.

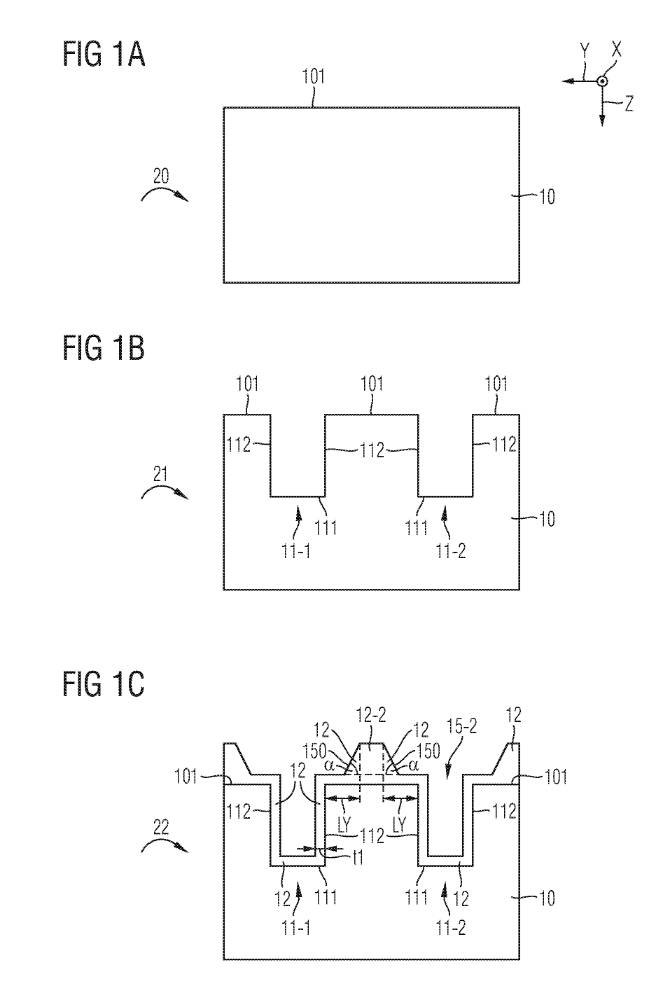

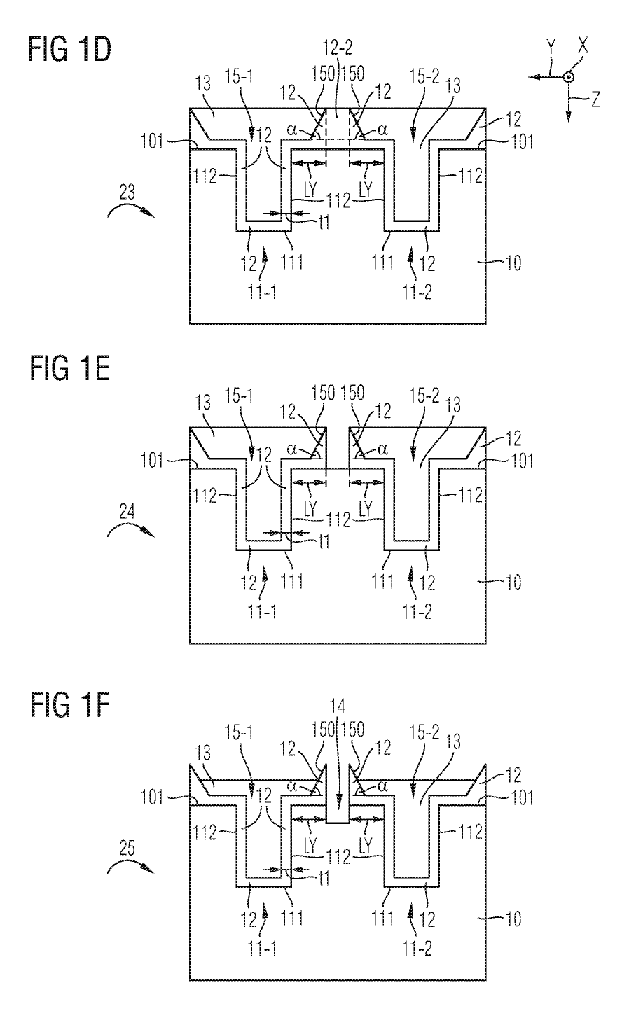

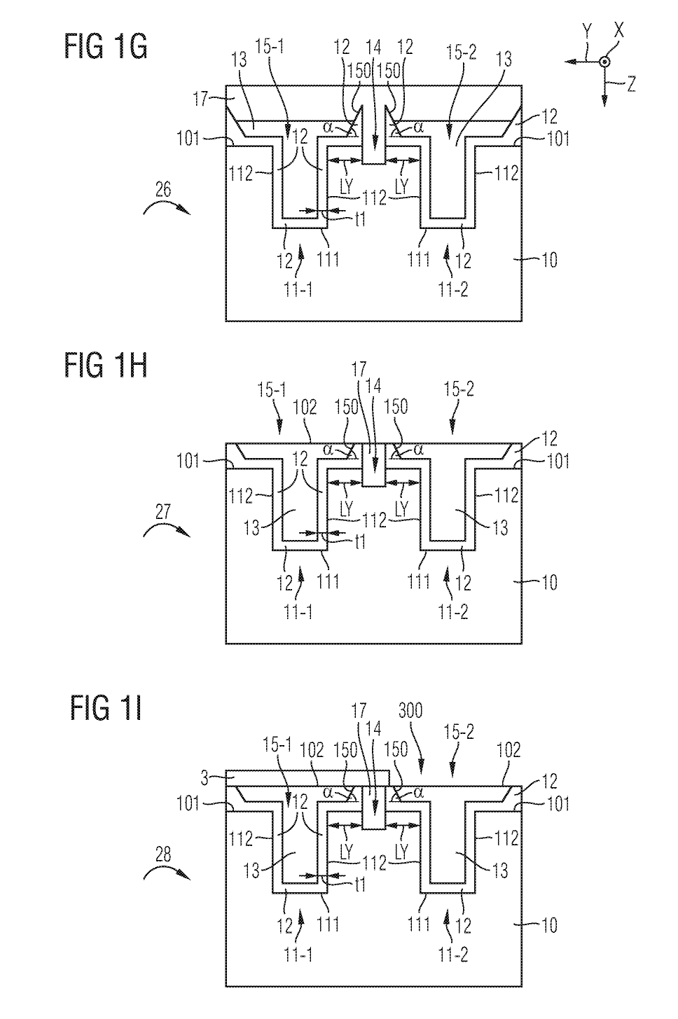

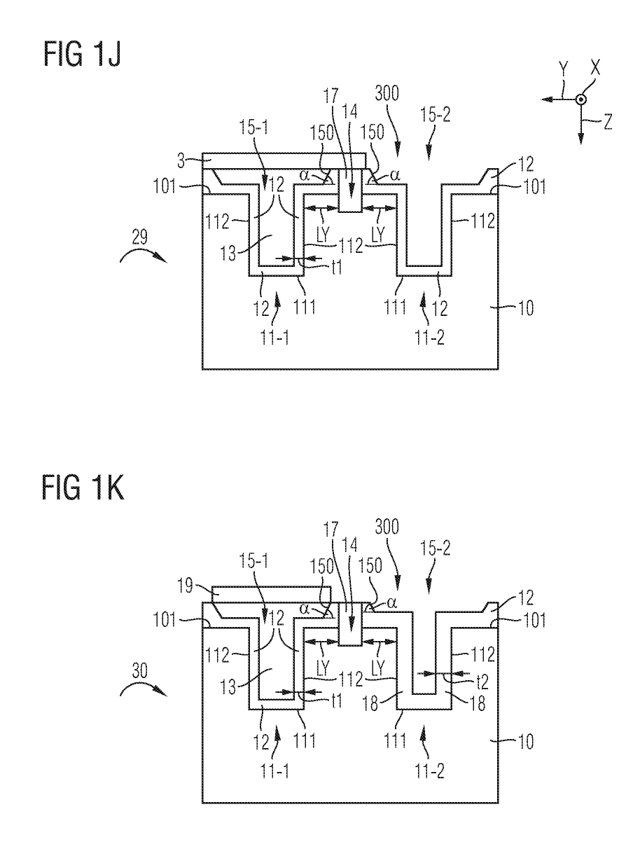

FIGS. 1A to 1K schematically illustrate different stages of a semiconductor device processing method 2 by means of the respective section of a vertical cross-section of the semiconductor device 1.

In the first step 20, a semiconductor body 10 is provided, as schematically illustrated in FIG. 1A. The semiconductor body 10 may extend laterally in the first lateral direction X and the second lateral direction Y and may further extend vertically along the vertical direction Z that may be perpendicular to each of the first lateral direction X and the second lateral direction Y. Further, the semiconductor body 10 may have a surface 101 that may extend substantially in parallel to a plane XY defined by the first and second lateral directions X and Y and substantially perpendicular to the vertical direction Z. For example, the semiconductor body 10 is provided in the form of the semiconductor wafer, wherein the surface 101 is formed by a surface of the semiconductor wafer.

After the semiconductor body 10 has been provided, a first recess 11-1 and a second recess 11-2 may be formed within step 21, as illustrated in FIG. 1B. Each recess 11-1, 11-2 may extend into the semiconductor body 10 from the surface 101 along the vertical direction Z. For example, each recess 11-1, 11-2 may exhibit a stripe configuration that extends laterally along the first lateral direction X. Further, each recess 11-1, 11-2 may be laterally confined by at least one recess sidewall 112 and may have a recess bottom 111. Creating the first and second recesses 11-1, 11-2 may, for example, comprise carrying out a masked etch process as known in the art.

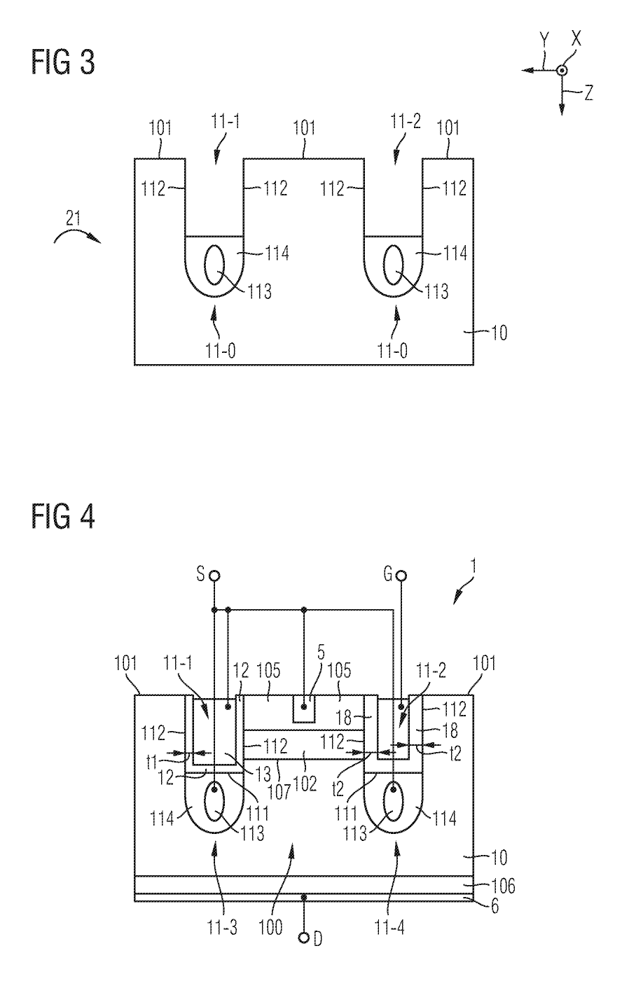

In a variant that is schematically illustrated in FIG. 3, the step 21 of creating the first and second recesses 11-1, 11-2 comprises creating at least two trenches 11-0 that extend into the semiconductor body 10 from the surface 101 along the vertical direction Z, wherein each of the trenches 11-0 includes, in a lower portion, a field plate 113 that is isolated from the semiconductor body 10 by an insulator 114.

For example, the field plates 113 comprise a conductive material such as a metal or polysilicon. The insulator 114 may comprise an oxide. The first recess 11-1 may be formed by an upper portion of one of the trenches 11-0 and the second recess 11-2 may be formed by an upper portion of the other trench 11-0.

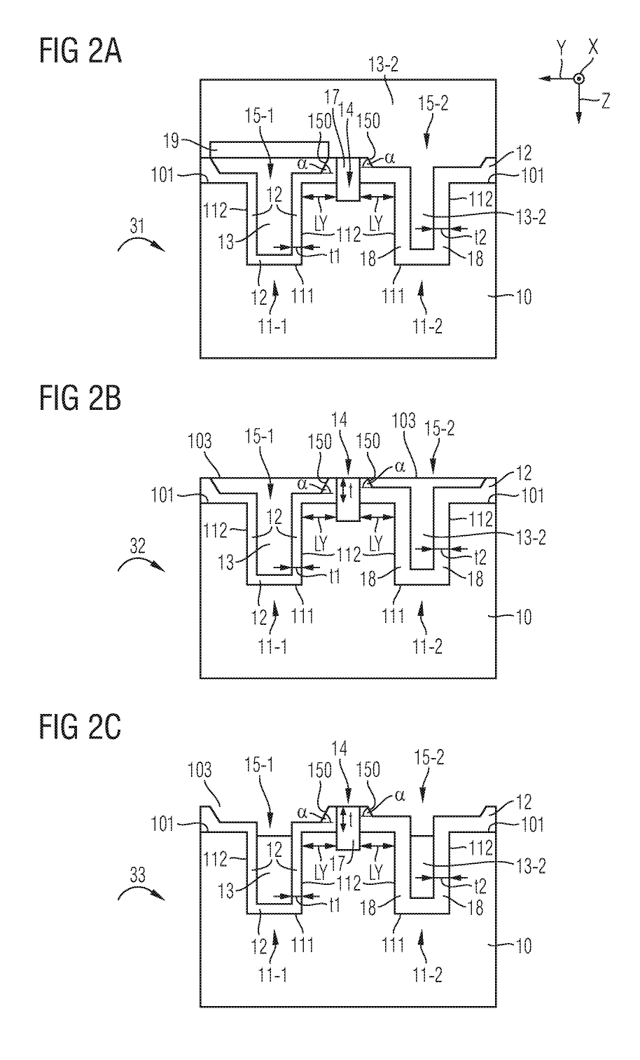

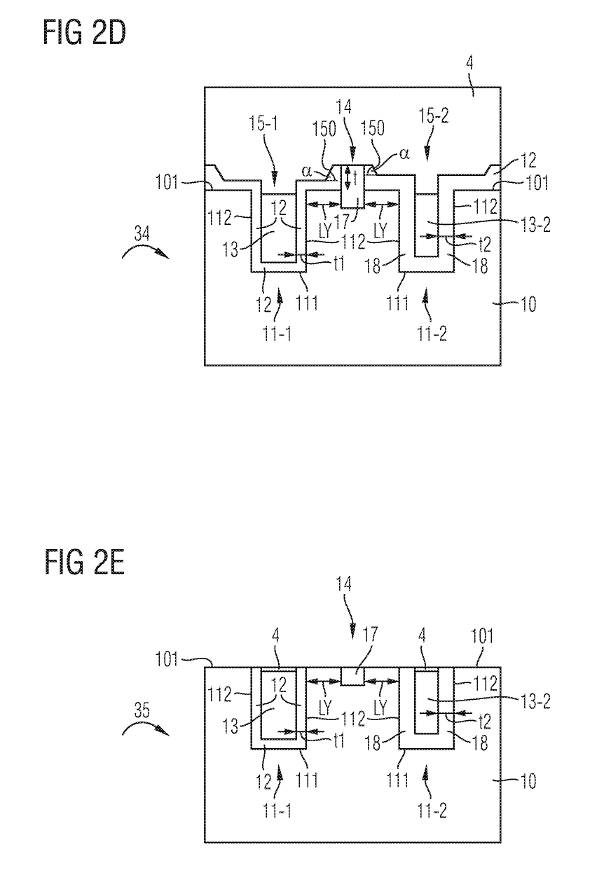

In all process stages described in the following with respect to FIGS. 1C to 2E, the semiconductor device 1 may comprise such trenches 11-0 as illustrated in FIG. 3, wherein the recesses 11-1, 11-2 are formed in the upper portions of said trenches 11-0, even if in FIGS. 1C to 2E the lower portions including said few plates 113 and set insulator 114 are not explicitly depicted.

In a further step 22, a first insulation layer 12 that covers the recess bottom 111 of each recess 11-1, 11-2, the at least one recess sidewall 112 of each recess 11-1, 11-2, and at least a portion of the surface 101 located between the first recess 11-1 and the second recess 11-2 may be created. As schematically illustrated in FIG. 1C, the first insulation layer 12 may form a first well 15-1 at the first recess 11-1 and a second well 15-2 at the second recess 11-2, wherein the first well 15-1 and the second well 15-2 each have a at least a respective common lateral extension range LY with the portion of the first insulation layer 12 located between the first recess 11-1 and the second recess 11-2.

In an embodiment, each of the wells 15-1, 15-2 exhibits at least one well sidewall 150 that extends substantially at an angle α with respect to a plane parallel to the surface 101 in the region of said common lateral extension range LY. The angle α may be chosen in dependence on a thickness of a middle portion 12-2 of the first insulation layer 12, see FIG. 1C. For example, the angle α may be in a range from 30° to 80°, in a range from 30° to 60°, in a range from 35° to 55°, or in a range from 40° to 50°. In an embodiment, the angle α is substantially 45°, such as in a range from 43° to 47°.

For example, creating the first insulation layer 12 comprises carrying out a high density plasma deposition (HDP), e.g. of an oxide such as silicon dioxide. Said angle α of the well sidewalls 150 may be defined by an appropriate choice of process parameters of the high density plasma deposition.

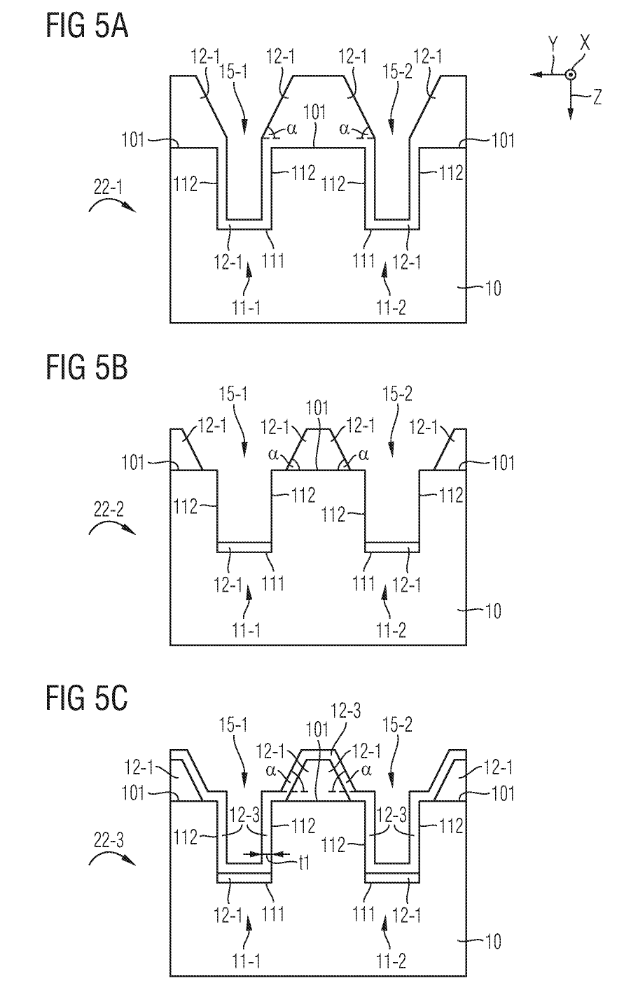

In a variant, creating the first insulation layer 12 comprises a first intermediate step 22-1, wherein an insulation layer 12-1 is formed initially as schematically illustrated in FIG. 5A. For example, the insulation layer 12-1 depicted in FIG. 5A may be formed using an HDP process, wherein the insulation layer 12-1 includes well sidewalls 150-1 oriented at said angle α with respect to the surface 101.

In a second intermediate step 22-2, the insulation layer 12-1 may be removed from the recess sidewalls 112 and from a portion of the surface 101 between the first recess 11-1 and the second recess 11-2, as shown in FIG. 5B. For example, removing said portions of the insulation layer 12-1 comprises carrying out an etch process, such as a wet etch process.

In a third intermediate step 22-3, as illustrated in FIG. 5C, an insulation layer 12-3 may be created so as to cover the sidewalls 112 of the recesses 11-1, 11-2, the insulation layer 12-1 on the surface 101, and the portions of the surface 101, from which the insulation layer 12-1 has been removed previously in the second intermediate step 22-2. In this way, the form of the first insulation layer 12 as depicted in FIG. 1C may be created. In other words, the first insulation layer as depicted in FIG. 1C may include the insulation layer 12-1, 12-3 shown in FIG. 5B. For example, the creating the insulation layer 12-3 in the third intermediate step 22-3 may comprise carrying out a deposition of an oxide, such as a tetraethyl orthosilicate (TEOS) deposition.

In a next process step 23, which may lead to a process stage as depicted in FIG. 1D, the first well 15-1 and the second well 15-2 may be filled at least partially with a plug material 13, such that in each well 15-1, 15-2 the plug material 13 has at least said respective common lateral extension range LY with the portion of the first insulation layer 12 located between the first recess 11-1 and the second recess 11-2.

In an embodiment, the plug material 13 comprises a first conductive material. For example, the first conductive material may comprise polysilicon.

According to an embodiment, said respective common lateral extension range LY is in a range from 5 nm to 1 μm.

In a next step 24, a middle portion 12-2 of the first insulation layer 12 located between the first recess 11-1 and the second recess 11-2 may be removed from the surface 101. As illustrated in FIG. 1D, the middle portion 12-2 may not have a common lateral extension range LY along the second lateral direction Y with the plug material 13. For example, the middle portion 12-2 is located substantially at the center of the surface 101 between the first recess 11-1 and the second recess 11-2 with respect to the second lateral direction Y.

In an embodiment, the step 24 of removing the middle portion 12-2 may comprise carrying out a selective plasma etch process. For example, the selective plasma etch process may be selective with respect to the material of the first insulation layer 12. For example, the plug material 13 may be substantially unaffected by said selective plasma etch process. Thus, the plug material 13 within the recesses 11-1, 11-2 may protect the first insulation layer 12 along said respective common lateral extension range LY so as to define the middle portion 12-2 to be removed during the selective plasma etch process. For example, such an etch process may be an anisotropic etch process, which may be directed substantially along the vertical direction Z.

In a further step 25. in a region where the middle portion 12-2 of the first insulation layer 12 has been removed from the surface 101 in step 24, a third recess 14 may be created. As illustrated in FIG. 1F, the third recess 14 may extend into the semiconductor body 10 from the surface 101 along the vertical direction Z. For example, creating the third recess 14 comprises carrying out a plasma etch process that is selective to silicon. The first insulation layer 12 may be substantially unaffected by said plasma etch process. Thus, the first insulation layer 12 may form a mask on the surface 101 for creating the third recess 14. The third recess 14 may be substantially centered between the first recess 11-1 and the second recess 11-2. In other words, the third recess 14 may be formed within the self-aligned process using the first insulation layer 12 as a mask.

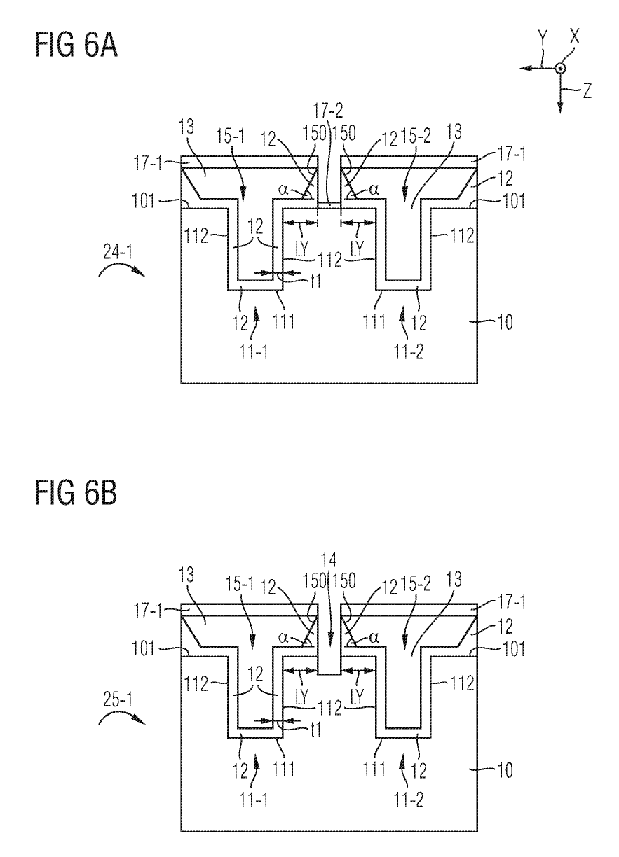

In a variant, before the third recess 14 is created, a protection layer 17-1 is created on top of the plug material 13 in an intermediate step 24-1, see FIG. 6A. For example, an oxide may be grown on top of the plug material 13 to form the protection layer 17-1. At the same time, as illustrated in FIG. 6A, an oxide 17-2 may be grown also on the surface 101 of the semiconductor body 10 where the middle portion 12-2 of the first insulation layer has been removed. For example, an oxidation of the plug material 13 and the surface 101 may be carried out such that the protection layer 17-1 formed on top of the plug material 13 is substantially thicker than the oxide layer 17-2 formed on the surface 101 where the middle portion 12-2 has been removed. Thus, during the subsequent step 25 of creating the third recess 14, e.g. via a plasma etch process, the plug material 13 may be protected by the protection layer 17-1, such that the plug material 13 remains substantially unaffected, e.g. by the plasma etch process, see FIG. 6B.

In a further step 26, as depicted in FIG. 1G, the third recess 14 and at least a portion of the space located between the first well 15-1 and the second well 15-2 are filled with a filling material 17. For example, an oxide deposition such as a TEOS deposition may be carried out for filling the third recess 14 and the space located between the first well 15-1 and the second well 15-2. As shown in FIG. 1G, the filling material may cover the third region 14, the first insulation layer 12, and the plug material 13.

In a further step 27, a first common surface 102 of the first insulation layer 12, the plug material 13, and the filling material 17 is created. The first common surface 102 may be essentially planar and parallel to the surface 101, as illustrated in FIG. 1H. For example, creating the first common surface 102 comprises a chemical-mechanical planarization (CMP) process. Such a CMP process may be configured so as to stop at the plug material 13. The filling material 17 and the first insulation layer 12 may thus be removed along the vertical direction Z down to the level of the plug material 13 within the recesses 11-1, 11-2, as shown in FIG. 1H. For example, cerium and/or a cerium compound may be used for such a CMP process.

In a further step 28, as schematically depicted in FIG. 1I, a mask 3 may be created on the common surface 102. The mask 3 may cover the plug material 13 in the first well 15-1, but may not or at least not completely cover the plug material 13 in the second well 15-2. In other words, the mask 3 may exhibit an opening 300 located above the plug material 13 in the second well 15-2. In a variant, the opening 300 may extend above only a part of the plug material 13 in the second well 15-2. In other words, the mask 3 may extend further along the second lateral direction than is depicted in FIG. 1I so as to cover, e.g., substantially half of second well 15-2. In another variant, the opening 300 may extend also above the recess 14, i.e., the mask 3 may not extend above the recess 14. For example, the mask 3 may be a hard mask comprising, e.g., nitride. Creating the mask 3 may comprise a lithographic process known in the art.

In a further step 29, the plug material 13 may be removed from the second well 15-2, as illustrated in FIG. 1J. For example, removing the plug material 13 from the second well 15-2 may comprise carrying out an etch process, such as an anisotropic etch process. In an embodiment, removing the plug material 13 from the second well 15-2 may comprise carrying out an isotropic etch process, such as an isotropic plasma etch process. The etch process may be selective with respect to the plug material. For example, the mask 3, the first insulation layer 12, and/or the filling material 14 may be substantially unaffected by such a selective etch process. The plug material 13 inside the first well 15-1 may be protected by the mask 3 during the etch process.

In a variant, at least a part of the first insulation layer 12 that covers the at least one recess sidewall 112 of the second recess 11-2 may be removed in a further step 29-1 after the plug material 13 has been removed from the second well 15-2 and from the second recess 11-2 in step 29. For example, removing a part of the first insulation layer 12 may comprise carrying out a plasma etch process. For example, such a plasma etch process may be selective to the material of the first insulation layer 12, e.g. silicon dioxide.

In a subsequent step 30, which may lead to a process stage as schematically illustrated in FIG. 1K, a second insulation layer 18 that covers the at least one recess sidewall 112 of the second recess 11-2 is created. For example, creating the second insulation layer 18 may comprise growing an oxide on the at least one recess sidewall 112 of the second recess 11-2 and/or on the first insulation layer 12 that covers the at least one recess sidewall 112 of the second recess 11-2. In another variant, creating the second insulation layer 18 may comprise a deposition of an oxide, such as the TEOS deposition. At the same time, an oxide 19 may be grown on top of the plug material in the first well 15-1, see FIG. 1K.

In an embodiment, the second insulation layer 18 at the at least one recess sidewall 112 of the second recess 11-2 may have a second thickness t2 that is greater than the first thickness t1 of the first insulation layer 12 at the at least one recess side wall hundred 12 of the first recess 11-1. For example the second thickness t2 may be greater than the first thickness t1 at least by a factor of 2, a factor of 10, or even at least by a factor of 20. In another embodiment, the first thickness t1 and the second thickness may be substantially equal. In yet another embodiment, the first thickness t1 may be greater than the second thickness t2 at least by a factor of 2, a factor of 10, or even at least by a factor of 20.

As illustrated in FIG. 2A, the method 2 may further comprise a step 31, wherein the second recess 11-2 is filled with a second conductive material 13-2. The second conductive material 13-2 may be the same material as the first conductive material 13. In another variant, the second conductive material 13-2 may be different from the first conductive material 13. For example, also the second conductive material 13-2 may comprise polysilicon. In an embodiment, both the first conductive material 13 and the second conductive material 13-2 may comprise polysilicon. For example, the polysilicon inside the first recess 11-1 may have a higher dopant concentration than the polysilicon inside the second recess 11-2. In another embodiment, the polysilicon inside the first recess 11-1 may have a lower dopant concentration than the polysilicon inside the second recess 11-2. In yet another embodiment, the polysilicon inside the first recess 11-1 and the polysilicon inside the second recess 11-2 may have substantially the same dopant concentration.

In a further embodiment, the method 2 further comprises a step 32 of creating a second common surface 103 of the first insulation layer 12, the plug material 13, the filling material 17, and the second conductive material 13-2, wherein the second common surface 103 is essentially planar and oriented substantially in parallel to the surface 101. The resulting process stage is schematically illustrated in FIG. 2B. For example, creating the second common surface 103 may comprise carrying out a CMP process, wherein, e.g., cerium and/or a cerium compound may be used. For example, such a CMP process may be carried out so as to remove the second conductive material 13-2 down to the level of the first insulation layer 12, as shown in FIG. 2B.

After the second common surface 103 has been created in step 32, a thickness t, which the first insulation layer 12 exhibits in the vicinity of the third recess 14, may be determined, see FIG. 2B. For example, the thickness t may be determined using optical methods known in the art.

In a subsequent step 33, a portion of the plug material 13 and of the second conductive material 13-2 may be removed using an etch process, such as a plasma etch process, that is carried out in dependence on the thickness t as determined previously. The etch process may be carried out such that the plug material 13 and the second conductive material 13-2 are removed down to a defined level below the surface 101, as shown in FIG. 2C. For example, the plug material 13 and the second conductive material 13-2 may be removed down to a level that is located within a range from 0 nm to 500 nm below the surface 101. In another embodiment, the second conductive material may be removed down to a level that is located deeper than 500 nm below the surface 101.

Referring now to FIG. 2D, the method 2 may further comprise a step 34, wherein a sacrificial material layer 4 is created on top of the first insulation layer 12, the plug material 13, the filling material 17, and the second conductive material 13-2. For example, creating the sacrificial material layer 4 may comprise at least one of a TEOS deposition, a high density plasma (HDP) to position, and a deposition of an undoped silicate glass (USG).

With reference to FIG. 2E, in a further step 35, the first insulation layer 12, the second insulation layer 18, the filling material 17, and the sacrificial material layer 4 are removed down to a level of the surface 101 using a CMP process. For example, cerium and/or a cerium compound may be used for the CMP process.

The method 2 may further comprise creating a source electrode 5 that extends at least partially inside the third recess 14, as illustrated in FIG. 4. For example, the source electrode 5 may comprise a conductive material, such as polysilicon or a metal. The source electrode 5 may be electrically connected to and/or form a part of a first load terminal S of the semiconductor device 1.

For example, the semiconductor device 1 is or includes a MOSFET, wherein the first load terminal S is a source terminal of the MOSFET. In another embodiment, the semiconductor device 1 may be or include an IGBT, wherein the first load terminal is an emitter terminal S of the IGBT. Accordingly, the method 2 may further comprise creating said first load terminal S.

Further, the method 2 may comprise creating a second load terminal D, e.g., at a backside of the semiconductor body, as depicted in FIG. 4. The second load terminal D may form, for example, one of a drain terminal of a MOSFET and a collector terminal of an IGBT. For example, a metallization layer 6 may be created at the backside of the semiconductor body 10, wherein the metallization layer 6 is electrically connected with or forms a part of the second load terminal.

The semiconductor device 1 may be configured to control a load current along a load current path between the first load terminal S and the second load terminal D. The load current may be controlled by means of a control electrode, sometimes referred to as gate electrode. For example, upon receiving a corresponding gate control signal from, e.g., a driver unit, the gate electrode may set the semiconductor device 1 in one of a conducting state and a blocking state.

In the embodiment illustrated in FIG. 4, a gate electrode of the semiconductor device 1 is formed by the second conductive material 13-2 inside the second recess 11-2. The second recess 11-2 including the second conductive material 13-2 may thus form a part of a transistor gate trench 11-4. The second conductive material 13-2 may be electrically connected with an external gate terminal G for receiving an external gate control signal. In a lower portion of the transistor gate trench 11-4, a field plate 113 as described above may be provided. For example, the field plate 113 may form a part of a compensation structure provided for reducing an average charge carrier density in the semiconductor body 10. As illustrated in FIG. 4, the field plate 113 may be electrically connected to the first load contact S.

Further, a source region 105 may be formed within the semiconductor body 10, wherein the source region 105 comprises dopants of a first conductivity type and is in contact with the source electrode 5. For example, the source region 105 may be n-doped if the semiconductor device 1 is an n-channel MOSFET or an n-channel IGBT, whereas the source region 105 may be p-doped in the case of a p-channel MOSFET or of a p-channel IGBT. The source region 105 may be created, e.g. by implantation and/or diffusion of dopants of the first conductivity type, after the third recess (14) has been created. For example, the source region 105 may extend along the second lateral direction Y continuously from a sidewall 112 of the second recess 11-2 to a sidewall 112 of the first recess 11-1, as illustrated in FIG. 4.

Further, a body region 102 having dopants of a second conductivity type complementary to the first conductivity type may be formed within the semiconductor body 10. The body region 102 may be created, e.g. by implantation and/or diffusion of dopants of the second conductivity type, after the third recess 14 has been created. In an embodiment, the body region 102 is created before the source region 105 is created. For example the source region 105 may be created by implantation and/or diffusion of dopants of the first conductivity type into the body region 102.

As illustrated in FIG. 4, the body region 102 may isolate the source region 105 from a drift region 100 provided within the semiconductor body 10. The drift region 100 has dopants of the first conductivity type, such that a pn-junction 107 is formed at a transition between the body region 102 and the drift region 100. For example, the body region 102 may extend along the second lateral direction Y continuously from a sidewall 112 of the second recess 11-2 to a sidewall 112 of the first recess 11-1, see FIG. 4.

The second conductive material 13-2 inside the second recess 11-2 may extend along the vertical direction Z at least as deep as the body region 102 extends along the vertical direction Z in the vicinity of the second insulation layer 18. In dependence on a gate voltage applied between the gate terminal G and the source terminal S, the gate electrode formed by the second conductive material 13-2 may be configured to induce an inversion channel inside the body region 102 in the vicinity of the second insulation layer 18. Thus, in a conducting state of the semiconductor device 1, the load current may flow between the source region 105 and the drift region 100 through the inversion channel. A threshold gate voltage corresponding to an onset of the current flow through the inversion channel may depend on the thickness t2 of the second insulation layer 18 and/or on properties of the second conductive material 13-2, such as a work function of the second conductive material 13-2.

Further, as illustrated in FIG. 4, the first conductive material 13 inside the first recess 11-1 may extend along the vertical direction Z at least as deep as the body region 102 extends along the vertical direction Z in the vicinity of the first insulation layer 12. For example, the first conductive material 13 in the first recess 11-1 may form a control electrode of a MOS gated diode (MGD), which may be configured to induce an inversion channel inside the body region 102 in the vicinity of the first insulation layer 12.

In an embodiment, the first conductive material 13 inside the first recess 11-1 may be electrically connected to the first load terminal S, as shown in FIG. 4. For example, said inversion channel may be formed if a reverse voltage is applied between the first load terminal S and the second load terminal D, wherein the reverse voltage is directed so as to forward bias the pn-junction 107. The inversion channel extending in the body region 102 in the vicinity of the first insulation layer 12 may then allow for a flow of a reverse current between the first load terminal and the second load terminal, wherein the reverse current is directed opposite to the load current that flows in the conducting state of the semiconductor device 1.

A threshold MGD gate voltage corresponding to an onset of the reverse current flow through the inversion channel at the first insulation layer 12 may depend on the thickness t1 of the first insulation layer 12 and/or on properties of the first conductive material 13, such as a work function of the first conductive material 13. For example, the second thickness t2 is greater than the first thickness t1 so as to provide for a gate voltage of the transistor 1 that is greater than the threshold MGD gate voltage.

In an alternative embodiment, the first conductive material 13 forming the control electrode of the MGD may not be electrically connected to the first load terminal S, but to a separate MGD terminal (not depicted).

The first recess 11-1 including the first conductive material 13 may thus form a part of an MGD gate trench 11-3. In a lower portion of the MGD gate trench 11-3, a field plate 113 as described above may be provided, see FIG. 4.

The embodiments schematically illustrated in FIG. 1A to FIG. 6B described above include the recognition that it may be sometimes desirable to produce a semiconductor device having a first control electrode and a second control electrode, wherein each control electrode extends into a semiconductor body within a respective first or second recess and is insulated from the semiconductor body by a first and second insulation layer, which may differ, e.g., in thickness. At the same time, it may desirable to create a third recess, e.g. a source contact groove, in between the first recess and the second recess via a self-aligned process.

In accordance with an embodiment, a first recess and a second recess are created, such that each recess extends into a semiconductor body from a surface. Subsequently a first insulation layer that covers a recess bottom of each recess, at least one recess side wall of each recess, and at least a portion of the surface located between the first recess and the second recess is created. The first insulation layer forms a first well at the first recess and a second well at the second recess, wherein the first well and the second well each have a respective common lateral extension range with the portion of the first insulation layer located between the first recess and the second recess. Subsequently, the first well and the second well are filled at least partially with a plug material, such that the plug material has said respective common lateral extension range with the portion of the first insulation layer located between the first recess and the second recess. A middle portion of the first insulation layer is then removed from the surface located between the first recess and the second recess, e.g. via a plasma etch process, wherein the middle portion is not protected by the plug material. Further, a third recess is created, in a region where the middle portion of the first insulation layer has been removed. Thus, the third recess is created via a self-aligned process using the plug material as a mask. In this way, a very precise positioning and dimensioning of the third recess between the first recess and the second recess may be achieved.

In a further step, the third recess and at least a portion of the space located between the first well and the second well is filled with the filling material and a first common surface of the first insulation layer, the plug material, and the filling material is created, e.g. via a CMP process. A mask is then created, wherein the mask completely covers the plug material in the first well and that does not completely cover the plug material in the second well. The plug material from the second well is removed, and a second insulation layer that covers the at least one recess side wall of the second recess is created.

Thus, with the method according to the invention, the precise positioning and dimensioning of the third recess via a self-aligned process and the creation of a first recess including a first insulation layer and a second recess including second insulation layer different from the first insulation layer may be combined.

Features of further embodiments are defined in the dependent claims. The features of further embodiments and the features of the embodiments described above may be combined with each other for forming additional embodiments, as long as the features are not explicitly described as being alternative to each other.

In the above, embodiments pertaining to power semiconductor transistors were explained. For example, these semiconductor transistors are based on silicon (Si). Accordingly, a monocrystalline semiconductor region or layer, e.g., the semiconductor regions 10, 101, 102, 105, 106 of exemplary embodiments, can be a monocrystalline Si-region or Si-layer. In other embodiments, polycrystalline or amorphous silicon may be employed.

It should, however, be understood that the semiconductor regions 10, 101, 102, 105, 106 can be made of any semiconductor material suitable for manufacturing a semiconductor device. Examples of such materials include, without being limited thereto, elementary semiconductor materials such as silicon (Si) or germanium (Ge), group IV compound semiconductor materials such as silicon carbide (SiC) or silicon germanium (SiGe), binary, ternary or quaternary III-V semiconductor materials such as gallium nitride (GaN), gallium arsenide (GaAs), gallium phosphide (GaP), indium phosphide (InP), indium gallium phosphide (InGaPa), aluminum gallium nitride (AlGaN), aluminum indium nitride (AlInN), indium gallium nitride (InGaN), aluminum gallium indium nitride (AlGaInN) or indium gallium arsenide phosphide (InGaAsP), and binary or ternary II-VI semiconductor materials such as cadmium telluride (CdTe) and mercury cadmium telluride (HgCdTe) to name few. The aforementioned semiconductor materials are also referred to as “homojunction semiconductor materials”. When combining two different semiconductor materials a heterojunction semiconductor material is formed. Examples of heterojunction semiconductor materials include, without being limited thereto, aluminum gallium nitride (AlGaN)-aluminum gallium indium nitride (AlGaInN), indium gallium nitride (InGaN)-aluminum gallium indium nitride (AlGaInN), indium gallium nitride (InGaN)-gallium nitride (GaN), aluminum gallium nitride (AlGaN)-gallium nitride (GaN), indium gallium nitride (InGaN)-aluminum gallium nitride (AlGaN), silicon-silicon carbide (SixC1-x) and silicon-SiGe heterojunction semiconductor materials. For power semiconductor devices applications currently mainly Si, SiC, GaAs and GaN materials are used.

Spatially relative terms such as “under”, “below”, “lower”, “over”, “upper” and the like, are used for ease of description to explain the positioning of one element relative to a second element. These terms are intended to encompass different orientations of the respective device in addition to different orientations than those depicted in the figures. Further, terms such as “first”, “second”, and the like, are also used to describe various elements, regions, sections, etc. and are also not intended to be limiting. Like terms refer to like elements throughout the description.

As used herein, the terms “having”, “containing”, “including”, “comprising”, “exhibiting” and the like are open ended terms that indicate the presence of stated elements or features, but do not preclude additional elements or features. The articles “a”, “an” and “the” are intended to include the plural as well as the singular, unless the context clearly indicates otherwise.

With the above range of variations and applications in mind, it should be understood that the present invention is not limited by the foregoing description, nor is it limited by the accompanying drawings. Instead, the present invention is limited only by the following claims and their legal equivalents.

What is claimed is:

1. A method of processing a semiconductor device, the method comprising:
providing a semiconductor body having a surface;
creating a first recess and a second recess, each recess extending into the semiconductor body from the surface along a vertical direction, wherein each recess has a recess bottom and is laterally confined by at least one recess sidewall;
creating a first insulation layer that covers the recess bottom of each recess, the at least one recess sidewall of each recess, and at least a portion of the surface located between the first recess and the second recess, the first insulation layer forming a first well at the first recess and a second well at the second recess, wherein the first well and the second well each have a respective common lateral extension range along a lateral direction with the portion of the first insulation layer located between the first recess and the second recess;
filling the first well and the second well at least partially with a plug material, such that the plug material has the respective common lateral extension range along the lateral direction with the portion of the first insulation layer located between the first recess and the second recess;
removing a middle portion of the first insulation layer located between the first recess and the second recess from the surface, wherein the middle portion does not have a common lateral extension range with the plug material;
creating, in a region where the middle portion of the first insulation layer has been removed, a third recess that extends into the semiconductor body from the surface along the vertical direction;
filling the third recess and at least a portion of the space located between the first well and the second well with a filling material;
creating a first common surface of the first insulation layer, the plug material, and the filling material, wherein the first common surface is essentially planar and parallel to the surface;
creating on the common surface a mask that completely covers the plug material in the first well and that does not completely cover the plug material in the second well;
removing the plug material from the second well; and
creating a second insulation layer that covers the at least one recess side wall of the second recess.

2. The method of claim 1, further comprising removing at least a part of the first insulation layer that covers the at least one recess side wall of the second recess before creating the second insulation layer.

3. The method of claim 1, wherein the first insulation layer at the at least one recess side wall of the first recess has a first thickness and the second insulation layer at the at least one recess side wall of the second recess has a second thickness, the second thickness being greater than the first thickness.

4. The method of claim 1, wherein creating the first insulation layer comprises carrying out a high density plasma deposition.

5. The method of claim 1, wherein creating the second insulation layer comprises growing an oxide on the at least one recess side wall of the second recess and/or on the first insulation layer covering the at least one recess side wall of the second recess.

6. The method of claim 1, wherein removing the middle portion comprises carrying out a selective plasma etch process.

7. The method of claim 1, wherein each of the wells comprise at least one well sidewall that extends substantially at an angle α with respect to a plane parallel to the surface in the region of the common lateral extension range, wherein the angle α is in the range from 30° to 80°.

8. The method of claim 1, wherein the plug material comprises a first conductive material.

9. The method of claim 1, further comprising filling the second recess with a second conductive material.

10. The method of claim 8, wherein the first conductive material and/or the second conductive material comprises polysilicon.

11. The method of claim 9, further comprising:
creating a second common surface of the first insulation layer, the plug material, the filling material, and the second conductive material, wherein the second common surface is essentially planar and parallel to the surface;
determining a thickness of the first insulation layer in the vicinity of the third recess; and
removing a portion of the plug material and of the second conductive material using an etch process that is carried out in dependence on the determined thickness such that the plug material and the second conductive material are removed down to a defined level below the surface.

12. The method of claim 11, further comprising:
creating a sacrificial material layer on top of the first insulation layer, the plug material, the filling material, the second insulation layer, and the second conductive material; and
removing the first insulation layer, the filling material, and the sacrificial material layer down to a level of the surface using a chemical-mechanical planarization process.

13. The method of claim 12, wherein at least one of cerium or a cerium compound is used for the chemical-mechanical planarization process.

14. The method of claim 1, wherein creating the first and second recesses comprises creating at least two trenches that extend into the semiconductor body from the surface along the vertical direction, each of the trenches comprising, in a lower portion, a field plate isolated from the semiconductor body by an insulator, wherein the first recess is formed by an upper portion of one of the trenches and the second recess is formed by an upper portion of the other trench.

15. The method of claim 1, further comprising creating a source electrode extending at least partially inside the third recess.

16. The method of claim 8, further comprising electrically connecting the first conductive material in the first recess to a source terminal of the semiconductor device.

17. The method of claim 9, further comprising electrically connecting the second conductive material to a gate terminal of the semiconductor device.

18. The method of claim 1, wherein the semiconductor device includes at least one of a MOSFET and an IGBT comprising at least one transistor gate trench that includes the first recess and at least one MOS gated diode gate trench that includes the second recess.

19. The method of claim 1, wherein the respective common lateral extension range is in a range from 5 nm to 1 μm.

20. The method of claim 1, further including creating a protection layer on top of the plug material before creating the third recess.
